(19) United States
(12) Patent Application Publication
(10) Pub. No.: US 2024/0111934 A1
(43) Pub. Date: Apr. 4, 2024

(54) DESIGN FOR TESTABILITY FOR FAULT DETECTION IN CLOCK GATE CONTROL CIRCUITS

(71) Applicant: QUALCOMM Incorporated, San Diego, CA (US)

(72) Inventors: Ripu SINGH, Leander, TX (US); Paul POLICKE, Cedar Park, TX (US); Preston MCWITHEY, Austin, TX (US)

(21) Appl. No.: 18/315,349

(22) Filed: May 10, 2023

Related U.S. Application Data
(60) Provisional application No. 63/410,456, filed on Sep. 27, 2022.

(51) Int. Cl. G06F 30/333

(52) U.S. Cl. CPC G06F 30/333

(57) ABSTRACT

An integrated circuit (IC), including: a set of cascaded clock gating control (CGC) circuits, wherein a first one of the set of cascaded CGC circuits includes a clock input configured to receive a clock signal; an observation flip-flop including a clock input coupled to a clock output of a last one of the set of cascaded CGC circuits; an input register configured to provide logic zeros (0s) to clock enable (CE) inputs of the set of cascaded CGC circuits pursuant to a stuck-at-one (SA1) fault testing on the CE input of a selected one of the set of cascaded CGC circuits; and a set of one or more test enable (TE) control registers configured to provide one or more logic ones (1s) to one or more TE inputs of one or more of the set of cascaded CGC circuits not undergoing the stuck-at-one (SA1) fault testing, respectively.

### CROSS-REFERENCE TO RELATED APPLICATION

This application claims the benefit of the filing date of U.S. Provisional Application, Ser. No. 63/410,456, filed on Sep. 27, 2022, which is incorporated herein by reference.

### FIELD

Aspects of the present disclosure relate generally to integrated circuits (ICs), and in particular, to a design for testability (DFT) for fault detection in clock gate control (CGC) circuits.

### BACKGROUND

An integrated circuit (IC) may include clock gate control (CGC) circuits to selectively provide a clock signal to functional circuits. A CGC circuit is often used as a power saving technique where if the functional circuit to which the CGC circuit provides the clock signal is not active at a particular time, the CGC circuit gates the clock signal so that the functional circuit does not consume power as a result of the clock signal. When the functional circuit is active, the CGC circuit then provides the clock signal so that the functional circuit is able to perform its synchronous operation based on the clock signal.

For design for testability (DFT), it may be desirable to test for stuck-at-faults at inputs and/or outputs of CGC circuits as such faults may adversely impact the functionality of the CGC circuits and the functional circuits to which the CGC circuits provide clock signals.

### SUMMARY

The following presents a simplified summary of one or more implementations in order to provide a basic understanding of such implementations. This summary is not an extensive overview of all contemplated implementations, and is intended to neither identify key or critical elements of all implementations nor delineate the scope of any or all implementations. Its sole purpose is to present some concepts of one or more implementations in a simplified form as a prelude to the more detailed description that is presented later.

An aspect of the disclosure relates to an integrated circuit (IC), including: a set of cascaded clock gating control (CGC) circuits, wherein a first one of the set of cascaded CGC circuits includes a clock input configured to receive a clock signal; an observation register including a clock input coupled to a clock output of a last one of the set of cascaded CGC circuits; an input register configured to provide logic zeros (0s) to clock enable (CE) inputs of the set of cascaded CGC circuits pursuant to a stuck-at-one (SA1) fault testing on the CE input of a selected one of the set of cascaded CGC circuits; and a set of one or more test enable (TE) control registers configured to provide one or more logic ones (1s) to one or more TE inputs of one or more of the set of CGC circuits not undergoing the stuck-at-one (SA1) fault testing, respectively.

Another aspect of the disclosure relates to a method. The method includes: providing a set of logic zeros (0s) to a set of clock enable (CE) inputs of a set of clock gating control (CGC) cascaded along a clock path to an observation register; configuring a subset of one or more of the set of CGC circuits not-under-test to be transparent with respect to the clock path; providing first and second logic values to input and output of the observation register, respectively; and providing a clock signal to an input of the clock path, wherein the first or second logic value at the output of the observation register in response to the clock signal indicates a stuck-at-one (SA1) fault or no SA1 fault at the CE input of the CGC circuit under-test, respectively.

Another aspect of the disclosure relates to an integrated circuit (IC), including: a clock gating control (CGC) circuit including a clock enable (CE) input, a clock input configured to receive a clock signal, and a clock output; an observation register including a data input, a clock input coupled to the clock output of the CGC circuit, a data output coupled to the CE input of the CGC circuit and the data input of the observation register, a scan-in (SIN) input configured to receive a logic one (1), and a scan enable (SE) input, wherein the observation register is configured to provide logic zeros (0s) to the CE input of the CGC circuit and the data input of the observation register pursuant to a stuck-at-one (SA1) fault testing on the CE input of the CGC circuit; and a test enable (TE) control register configured to provide a logic one (1) to the SE input of the observation register pursuant to the stuck-at-one (SA1) fault testing at the CE input of the CGC circuit.

Another aspect of the disclosure relates to a method. The method includes: providing a logic zero (0) at an output of an observation register to a data input of the observation register and a clock enable (CE) input of a clock gating control (CGC) circuit; and providing a clock signal to a clock signal path including the CGC circuit and the observation register, wherein a logic one (1) at the output of the observation register in response to the clock signal indicates a stuck-at-one (SA1) fault at the CE input of the CGC circuit, and wherein a logic zero (0) at the output of the observation register in response to the clock signal indicates no stuck-at-one (SA1) fault at the CE input of the CGC circuit.

To the accomplishment of the foregoing and related ends, the one or more implementations include the features hereinafter fully described and particularly pointed out in the claims. The following description and the annexed drawings set forth in detail certain illustrative aspects of the one or more implementations. These aspects are indicative, however, of but a few of the various ways in which the principles of various implementations may be employed and the description implementations are intended to include all such aspects and their equivalents.

### BRIEF DESCRIPTION OF THE DRAWINGS

FIG. 1 illustrates a block diagram of an example integrated circuit (IC) including design for testability (DFT) hardware for fault detection in cascaded clock gate control (CGC) circuits in accordance with an aspect of the disclosure.

FIG. 2 illustrates a block diagram of another example integrated circuit (IC) including design for testability (DFT) hardware for fault detection in cascaded clock gate control (CGC) circuits in accordance with another aspect of the disclosure.

FIG. 3 illustrates a block diagram of another example integrated circuit (IC) including design for testability (DFT) hardware for fault detection in cascaded clock gate control (CGC) circuits in accordance with another aspect of the disclosure.

FIG. 4 illustrates a block diagram of another example integrated circuit (IC) including design for testability (DFT) hardware for fault detection in cascaded clock gate control (CGC) circuits in accordance with another aspect of the disclosure.

FIG. 5 illustrates a block diagram of another example integrated circuit (IC) including design for testability (DFT) hardware for fault detection in cascaded clock gate control (CGC) circuits in accordance with another aspect of the disclosure.

FIG. 6 illustrates a block diagram of another example integrated circuit (IC) including design for testability (DFT) hardware for fault detection in cascaded clock gate control (CGC) circuits in accordance with another aspect of the disclosure.

FIG. 7 illustrates a block diagram of another example integrated circuit (IC) including design for testability (DFT) hardware for fault detection in a set of N cascaded clock gate control (CGC) circuits in accordance with another aspect of the disclosure.

FIG. 8 illustrates a block diagram of another example integrated circuit (IC) including design for testability (DFT) hardware for fault detection in a clock gate control (CGC) circuit in accordance with another aspect of the disclosure.

FIG. 9 illustrates a block diagram of another example integrated circuit (IC) including design for testability (DFT) hardware for fault detection in a clock gate control (CGC) circuit in accordance with another aspect of the disclosure.

FIG. 10 illustrates a block diagram of another example integrated circuit (IC) including design for testability (DFT) hardware for fault detection in a clock gate control (CGC) circuit in accordance with another aspect of the disclosure.

FIG. 11 illustrates a flow diagram of an example method of fault testing regarding a set of cascaded clock gate control (CGC) circuits in accordance with another aspect of the disclosure.

FIG. 12 illustrates a flow diagram of an example method of fault testing a clock gate control (CGC) circuit in accordance with another aspect of the disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

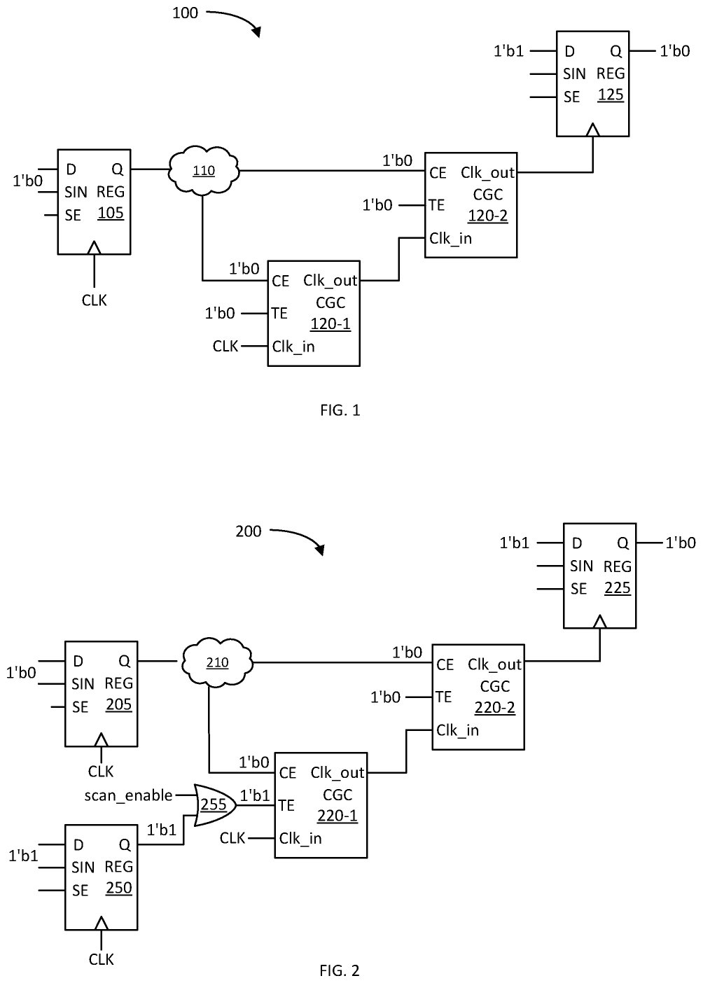

FIG. 1 illustrates a block diagram of an example integrated circuit (IC) 100 including design for testability (DFT) hardware for fault detection in cascaded clock gate control (CGC) circuits in accordance with an aspect of the disclosure. The IC 100 includes an input register (REG) 105 configured to provide test data bits in response to a clock signal (CLK) for DFT purposes (the register 105 may be referred to as the dominant logic register as it may be the primary register that applies test data to the CGCs). The IC 100 further includes a set of cascaded (clock output-to-clock input) clock gate control (CGC) circuits 120-1 and 120-2, wherein the CGC circuit 120-1 is a first stage of the cascaded set, and the CGC circuit 120-2 is a second or last stage of the cascaded set.

The input register 105 includes a clock input configured to the clock signal (CLK) (e.g., a periodic oscillating signal, often substantially square wave in waveform). The input register 105 may include a data (D) input and a scan-in (SIN) input configured to receive functional and test data. Additionally, the input register 105 includes a scan enable (SE) to receive a scan_enable signal that controls whether the test data at the D input or SIN input is transferred to the data (Q) output. Also, as mentioned above, the input register 105 is configured to transfer the test data from the D input or SIN input to the Q output in response to an edge (e.g., a rising or falling edge) of the clock signal CLK.

The first stage CGC circuit 120-1 includes a clock enable (CE) input, a test enable (TE) input, a clock input (Clk_in) configured to receive the clock signal CLK, and a clock output (Clk_out). In operation, if the data at the TE input is a 1′b0 (a logic zero (0)), the data at the CE input controls whether the first stage CGC circuit 120-1 transfers the clock signal CLK from the Clk_in input to the Clk_out output. Thus, if the data at the CE input is a 1′b0, the first stage CGC circuit 120-1 does not transfer the clock signal CLK to the Clk_out output. If the data at the CE inputs is a 1′b1 (a logic one (1)), the first stage CGC circuit 120-1 transfers the clock signal CLK to the Clk_out output. Similarly, if the data at the TE input is a 1′b1, the first stage CGC circuit 120-1 transfers the clock signal CLK to the Clk_out output regardless of what the data is at the CE input. The second stage CGC circuit 120-2 operates in the same manner discussed above with respect to the first stage CGC circuit 120-1.

The Q output of the input register 105 may be coupled to the CE inputs of the first and second stages CGC circuits 120-1 and 120-2 by way of some logic circuitry 110 (represented generally as a cloud). The TE inputs of the first and second stages CGC circuits 120-1 and 120-2 may receive the same test enable signal, which, in this example, is a 1′b0. The Clk_out output of the first stage CGC circuit 120-1 is coupled to the Clk_in input of the second stage CGC circuit 120-2.

The IC 100 further includes an observation register 125 configured to generate a test result data at a Q output indicative of a test conducted on the CGC circuits 120-1 and 120-2; and in particular, in this example, on the second stage CGC circuit 120-2, as discussed in more detail further herein. An input observation bit, such as a 1′b1 in this example, may be applied to a D input, or a SIN input of the observation register 125 with a control data applied to an SE input to cause the observation register 125 to transfer the observation bit to the Q output. The Q output may be set to the opposite logic state as the observation bit, such as a 1′b0 in this example.

In this example, a test may be performed to determine stuck-at-faults at the CE input of the second stage CGC circuit 120-2. A stuck-at-zero (“SA0”), which is a condition where the CE input is stuck at a logic zero (0) (e.g., there is a short connecting a lower voltage rail Vss to the CE input), may be tested for in accordance with the DFT hardware configuration of IC 100. Per such test, the input register 105 may transfer a 1′b1 to the CEs of the first and second stage CGC circuits 120-1 to 120-2. If there are no stuck-at-zero (SA0) fault at the CE input of the first stage CGC 120-1, the 1′b1 at the CE input causes the first stage CGC 120-1 to output the clock signal CLK, and the second stage CGC circuit 120-2 receives the clock signal CLK from the first stage CGC circuit 120-1.

If there is also no stuck-at-zero (SA0) fault at the CE input of the second stage CGC

circuit 120-2, the 1′b1 at the CE input causes the second stage CGC 120-2 to output the clock signal CLK, and the clock signal CLK is provided to the clock input of the observation register 125. In response to the clock signal CLK, the observation register 125 transfers the observation data (e.g., 1′b1) at the D or SIN input to its Q output. As the data of the Q output prior to the data transfer is at the opposite logic state as the observation data (e.g., 1′b0), a change in the data at the Q output indicates no stuck-at-zero (SA0) fault at the CE of the second stage CGC circuit 120-2. On the other hand, no change in the data at the Q output may indicate a stuck-at-zero (SA0) fault at the CE input of the second stage CGC circuit 120-2.

However, based on the DFT hardware configuration of the IC 100, a test to determine a stuck-at-one (“SA1”) fault at the CE input of the second stage CGC circuit 120-2 may not be attainable. A stuck-at-one (SA1) is a condition where the CE input is stuck at a logic one (1) (e.g., there is a short connecting an upper voltage rail Vdd to the CE input). Per such test attempt, the input register 105 transfers a 1′b0 to the CEs of the first and second stages CGC circuits 120-1 to 120-2. As the CE input of the first stage CGC circuit 120-1 is a 1′b0, the first stage CGC circuit 120-1 does not output the clock signal CLK. The clock signal CLK is needed by the second stage CGC circuit 120-2 to determine whether there is a stuck-at-one (SA1) fault at the CE input of the second stage CGC circuit 120-2. Thus, a stuck-at-one (SA1) fault at the CE input of the second stage CGC circuit 120-2 cannot be tested for with the DFT hardware configuration of the IC 100.

FIG. 2 illustrates a block diagram of another example integrated circuit (IC) 200 including design for testability (DFT) hardware for fault detection in cascaded clock gate control (CGC) circuits in accordance with another aspect of the disclosure. The IC 200 includes a DFT hardware configuration that allows for testing for a stuck-at-one (SA1) fault at the CE input of a second stage CGC circuit.

The IC 200 is a modified version of the IC 100, and includes a number of same/similar elements as indicated by the same reference numbers with the exception that the most significant digit is a “2” in IC 200 compared to a “1” in IC 100. That is, the IC 200 includes a dominant logic input register 205, some optional logic circuitry 210, a set of cascaded CGC circuits 220-1 and 220-2, and an observation register 225. Similarly, the input register 205 is configured to output a test data to the CE inputs of the first and second stage CGC circuits 220-1 and 220-2 via the logic circuitry 210. The Clk_in input of the first stage CGC circuit 220-1 is configured to receive the clock signal CLK. The Clk_out output of the first stage CGC circuit 220-1 is coupled to the Clk_in input of the second stage CGC circuit 220-2. The TE input of the second CGC circuit 220-2 is configured to receive a test enable signal which, in this example, is at 1′b0 to allow for stuck-at-fault testing at the CE input of the second CGC circuit 220-2.

As mentioned above, the IC 200 includes a DFT hardware configuration that allows for testing for a stuck-at-one (SA1) fault at the CE input of the second stage CGC circuit 220-2. In this regard, the IC 200 includes a test enable (TE) control register 250 and an OR gate 255. The TE control register 250 may receive a programmable test data via the D or SIN input, and output the programmable test data to a first input of the OR gate 255 in response to the clock signal CLK (with the input to the SE input set accordingly). During scan-in phase, the scan_enable is asserted at 1′b1 to maintain the TE input of the first stage CGC circuit 220-1 at 1′b1 to enable the propagation of the clock signal CLK. At the end of the scan-in phase, the programmable test data at the Q output of the TE control register 250 is provided to the TE input of the first stage CGC circuit 220-1.

In accordance with the stuck-at-one (SA1) testing at the CE input of the second stage CGC circuit 220-2, the dominant logic register 205 provides a 1′b0 to the CE inputs of the first and second stage CGC circuits 220-1 and 220-2 in response to the clock signal CLK. In clock synchronous, the TE control register 250 provides a 1′b1 to the TE input of the first stage CGC circuit 220-1. In contrast to the DFT hardware configuration of IC 100, the 1′b1 at the TE input makes the first stage CGC circuit 220-1 transparent with respect to the clock signal CLK. That is, the first stage CGC circuit 220-1 transfers the clock signal CLK to the Clk_in input of the second stage CGC circuit 220-2.

Thus, if there is a stuck-at-one (SA1) fault at the CE input of the second stage CGC circuit 220-2, a 1′b1 is at the CE input even though the dominant logic register 205 provided a 1′b0 to the CE input. Accordingly, the second stage CGC circuit 220-2 transfers the clock signal CLK to the clock input of the observation register 225 causing it to transfer the observation data (e.g., 1′b1) at the D or SIN input to the Q output, which was previously at the opposite logic state as the observation data (e.g., 1′b0). The transfer of the observation data causes the Q output to change logic states, which indicates a stuck-at-one (SA1) fault at the CE input of the second stage CGC circuit 220-2.

If there were no stuck-at-one (SA1) fault at the CE input of the second stage CGC circuit 220-2, the CE input would have a 1′b0, and accordingly, the second stage CGC circuit 220-2 would not transfer the clock signal CLK to the observation register 225; and thus, the observation register 225 would not transfer the observation data from the D or SIN input to the Q output. Thus, a no change in the logic state at the Q output would indicate no stuck-at-one (SA1) fault at the CE input of the second stage CGC circuit 220-2.

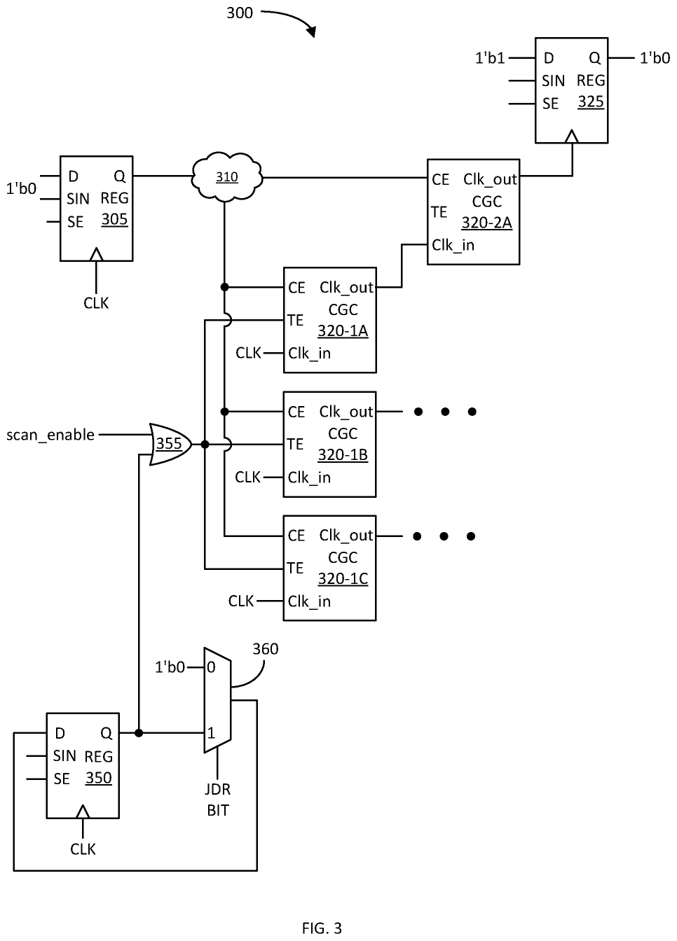

FIG. 3 illustrates a block diagram of another example integrated circuit (IC) 300 including design for testability (DFT) hardware for fault detection in cascaded clock gate control (CGC) circuits in accordance with another aspect of the disclosure. The IC 300 is a variation of the IC 200 including many same/similar elements as indicated with the same reference numbers with the exception that the most significant digit is a “3” in IC 300 compared to a “2” in IC 200.

In particular, the IC 300 includes an input dominant logic register 305, some optional logic circuitry 310, a set of parallel first stage CGC circuits 320-1A, 320-1B, and 320-1C, a second stage CGC circuit 320-2A for the first stage CGC circuit 320-1A, and an observation register 325. Although not shown, it shall be understood that second stage CGC circuits including observation registers may be coupled to the outputs of the first stage CGC circuits 320-1B and 320-1C, respectively. Additionally, to enable stuck-at-one (SA1) fault testing at the CE input of the second stage CGC circuit 320-2A, as discussed in detail with reference to IC 200, the IC 300 includes a TE control register 350 and OR gate 355. As there are a plurality of first stage CGC circuits 320-1A to 320-1C in this example, the output of the OR gate 355 may be provided to the TE inputs of the set of parallel first stage CGC circuits 320-1A to 320-1C.

For implementation detectability, the IC 300 includes a multiplexer 360 including a “0” input configured to receive a 1′b0 bit and a “1” input coupled to the Q output of the TE control register 350. The multiplexer 360 includes a select input configured to receive a Joint Test Action Group (JTAG) data register (JDR) bit. When the JDR bit is a “1”, the operation of the TE control register 350 is as described with reference to IC 200 (e.g., to provide a 1′b1 to the TE inputs of the first stage CGC circuits 320-1A and 320-1C. However, if the JDR bit is flipped to a “0”, after the clock edge causes the TE control register 350 to transfer a 1′b1 to the TE inputs of the first stage CGC circuits 320-1A and 320-1C, a “0” will end up at the D input of the TE control register 350. When the vectors are scanned out for observation, the TE control register 350 will fail test because there is an expectation of a “1” at the D input of the TE control register 350 when a “0” is observed at the D input. Thus, using this technique, detectability and location of the TE control register 350 may be determined.

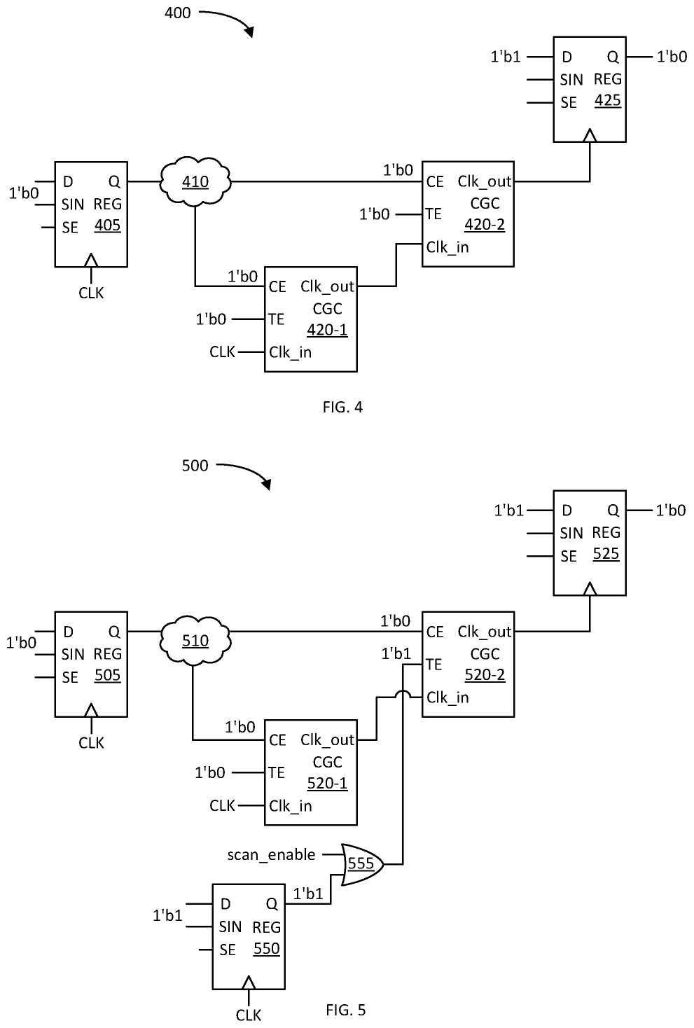

FIG. 4 illustrates a block diagram of another example integrated circuit (IC) 400 including design for testability (DFT) hardware for fault detection in cascaded clock gate control (CGC) circuits in accordance with another aspect of the disclosure. The IC 400 is similar to the IC 100 with many same/similar elements as indicated by the same reference numbers with the exception that the most significant digit is a “4” in IC 400 compared to a “1” in IC 100. That is, the IC 400 includes an input dominant logic register 405, some optional logic circuitry 410, a first stage CGC circuit 420-1, a second stage CGC circuit 420-2, and an observation register 425. These elements are also arranged and coupled together in the same/similar manner as the same/similar elements of IC 100.

Similar to IC 100, the IC 400 has a DFT issue with respect to testing for a stuck-at-one

(SA1) fault at the CE input of the first stage CGC circuit 420-1. For example, the input register 405 transfers a 1′b0 to the CE inputs of the first and second stage CGC circuits 420-1 and 420-2 per the clock signal CLK. The test enable signal at 1′b0 is applied to the TE inputs of the first and second stage CGC circuits 420-1 and 420-2. The clock signal CLK is also applied to the Clk_in input of the first stage CGC circuit 420-1.

Because a 1′b0 is provided to the CE input of the second stage CGC circuit 420-2, the second stage CGC circuit 420-2 is non-transparent, and will not propagate the clock signal CLK at its Clk_in input to its Clk_out output. Accordingly, the observation register 425 will not be clocked in this test scenario; and thus, a determination as to whether there is a stuck-at-one (SA1) fault at the CE input of the first stage CGC circuit 420-1 cannot be made.

FIG. 5 illustrates a block diagram of another example integrated circuit (IC) 500 including design for testability (DFT) hardware for fault detection in cascaded clock gate control (CGC) circuits in accordance with another aspect of the disclosure. As discussed in more detail further herein, the IC 500 includes a similar TE control register and OR gate as discussed with IC 200 to effectuate stuck-at-one (SA1) fault testing at the CE input of a first stage CGC circuit.

Accordingly, the IC 500 is a variation of IC 400 including some of the same/similar elements as indicated by the same reference numbers with the exception that the most significant digit is a “5” in IC 500 compared to a “4” in IC 400. That is, the IC 500 includes an input dominant logic register 505, some optional logic circuitry 510, a first stage CGC circuit 520-1, a second stage CGC circuit 520-2, and an observation register 525. These elements are also arranged and coupled together in the same/similar manner as the same/similar elements of IC 400.

As mentioned above, the IC 500 includes a DFT hardware configuration that allows for testing for a stuck-at-one (SA1) fault at the CE input of the first stage CGC circuit 520-1. In this regard, the IC 500 includes a test enable (TE) control register 550 and an OR gate 555. The TE control register 550 may receive a programmable test data via the D or SIN input, and output the programmable test data to a first input of the OR gate 555 in response to the clock signal CLK (with the input to the SE input set accordingly). During scan-in phase, the scan_enable is asserted at 1′b1 to maintain the TE input of the second stage CGC circuit 520-2 at 1′b1 to enable the propagation of the clock signal CLK. At the end of the scan-in phase, the programmable test data at the Q output of the TE control register 550 is provided to the TE input of the second stage CGC circuit 520-2.

In accordance with the stuck-at-one (SA1) testing at the CE input of the first stage CGC circuit 520-1, the dominant logic register 505 provides a 1′b0 to the CE inputs of the first and second stage CGC circuits 520-1 and 520-2 in response to the clock signal CLK. In clock synchronous, the TE control register 550 provides a 1′b1 to the TE input of the second stage CGC circuit 520-2. In contrast to the DFT hardware configuration of IC 400, the 1′b1 at the TE input makes the second stage CGC circuit 520-2 transparent with respect to the clock signal CLK. Thus, the second stage CGC circuit 520-2 is able to propagate the clock signal CLK to the observation register 525 if the clock signal CLK is present in its Clk_in input.

Thus, if there is a stuck-at-one (SA1) fault at the CE input of the first stage CGC circuit 520-1, a 1′b1 is at the CE input even though the dominant logic register 505 provided a 1′b0 to the CE input. Accordingly, the first stage CGC circuit 520-1 transfers the clock signal CLK to the clock input of the second stage CGC circuit 520-2 which, in turn, transfers the clock signal CLK to the observation register 525 causing it to transfer the observation data (e.g., 1′b1) at the D or SIN input to the Q output. As the Q output of the observation register 525 was previously at an opposite logic state as the observation data (e.g., 1′b0), the transfer of the observation data causes the Q output to change logic states, which indicates a stuck-at-one (SA1) fault at the CE input of the first stage CGC circuit 520-1.

If there were no stuck-at-one (SA1) fault at the CE input of the first stage CGC circuit 520-1, the first stage CGC circuit 520-1 would not transfer the clock signal CLK to the second stage CGC circuit 520-2 which, in turn, does not transfer the clock signal CLK to the observation register 525. Thus, the observation register 525 would not transfer the observation data from the D or SIN input to the Q output. Thus, a no change in the logic state at the Q output would indicate no stuck-at-one (SA1) fault at the CE input of the first stage CGC circuit 520-1.

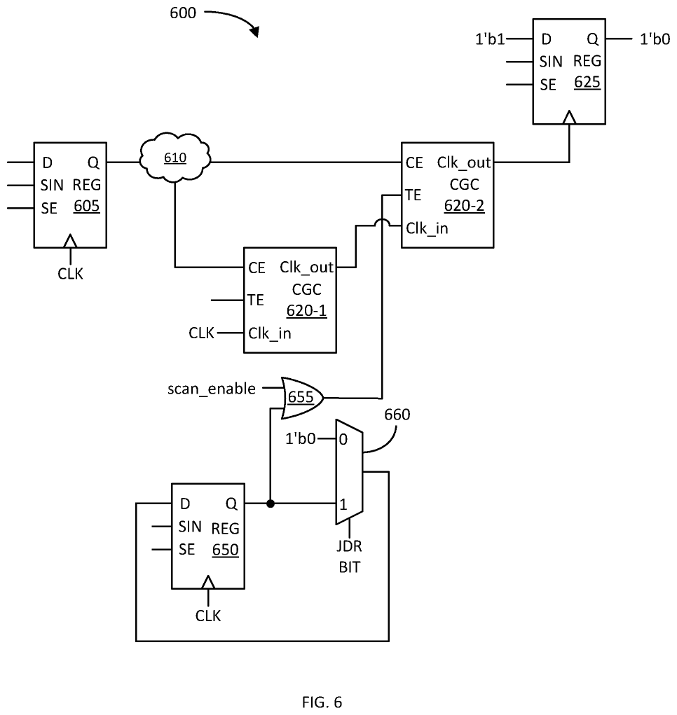

FIG. 6 illustrates a block diagram of another example integrated circuit (IC) including design for testability (DFT) hardware for fault detection in cascaded clock gate control (CGC) circuits in accordance with another aspect of the disclosure. The IC 600 is a variation of the IC 500 including many same/similar elements as indicated with the same reference numbers with the exception that the most significant digit is a “6” in IC 600 compared to a “5” in IC 500.

In particular, the IC 600 includes an input dominant logic register 605, some optional logic circuitry 610, a first stage CGC circuit 620-1, a second stage CGC circuit 620-2, and an observation register 625. Additionally, to enable stuck-at-one (SA1) fault testing at the CE input of the first stage CGC circuit 620-1, as discussed in detail with reference to IC 500, the IC 600 includes a TE control register 650 and an OR gate 655.

For implementation detectability, the IC 600 includes a multiplexer 660 including a “0” input configured to receive a 1′b0 bit, and a “1” input coupled to the Q output of the TE control register 650. The multiplexer 660 includes a select input configured to receive a JDR bit. When the JDR bit is a “1”, the operation of the TE control register 650 is as described with reference to IC 500 (e.g., to provide a 1′b1 to the TE input of the second stage CGC circuit 620-2). However, if the JDR bit is flipped to a “0”, after the clock edge causes the TE control register 650 to transfer a 1′b1 to the TE input of the second stage CGC circuit 620-2, a “0” will end up at the D input of the TE control register 650. When the vectors are scanned out for observation, the TE control register 650 will fail test because there is an expectation of a “1” at the D input of the TE control register 650 when a “0” is observed at the D input. Thus, using this technique, detectability and location of the TE control register 650 may be determined.

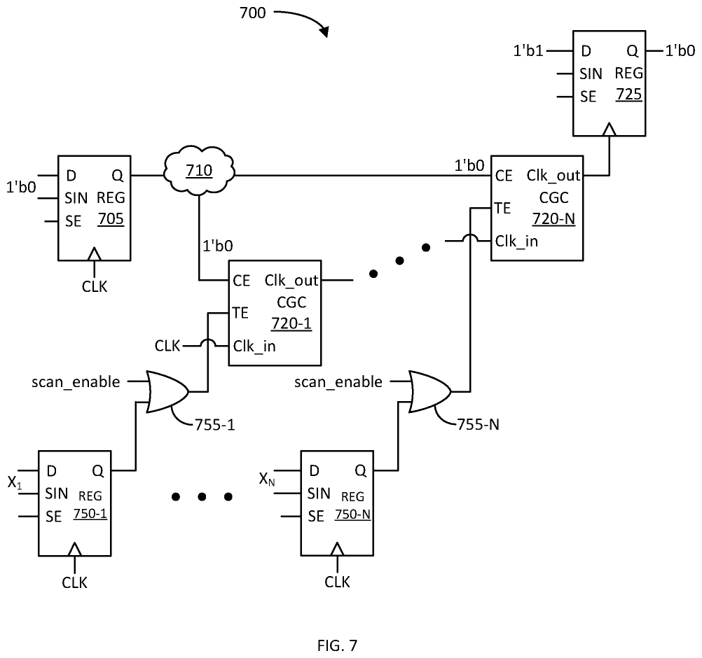

FIG. 7 illustrates a block diagram of another example integrated circuit (IC) 700 including design for testability (DFT) hardware for fault detection in a set of N cascaded clock gate control (CGC) circuits in accordance with another aspect of the disclosure. The IC 700 may be a combination of the ICs 200 and 500 previously discussed, and extended to a set of N cascaded CGC circuits, where N is a positive integer. That is, the IC 700 includes a DFT hardware configuration that allows for testing for stuck-at-one (SA1) faults any of the CE inputs of a set of N cascaded CGC circuits.

In particular, the IC 700 includes an input dominant logic register 705, some optional logic circuitry 710, a set of N cascaded CGC circuits 720-1 to 720-N, an observation register 725, and a set of N TE control registers 750-1 to 750-N including a set of associated OR gates 755-1 to 755-N, respectively. Similarly, in response to a clock signal CLK, the input register 705 is configured to output a test data to the CE inputs of the set of N cascaded CGC circuits 720-1 to 720-N via the logic circuitry 710. The Clk_in input of the first stage CGC circuit 720-1 is configured to receive the clock signal CLK. The Clk_out outputs of the cascaded CGC circuits 720-1 to 720-N are coupled to the Clk_in inputs of the cascaded CGC circuits 720-2 to 720-N and the clock input of the observation register 725, respectively. The observation register 725 may be preloaded with opposite logic states at its input (e.g., 1′b1) and output (e.g., 1′b0), respectively.

As mentioned above, the IC 700 includes a DFT hardware configuration that allows for testing for stuck-at-one (SA1) faults at any of the CE inputs of the set of N cascaded CGC circuits 720-1 to 720-N, respectively. In this regard, each of the TE control registers 750-1 to 750-N may receive a set of programmable test data X₁ to X_{N} via the D or SIN input, and output the set of programmable test data X₁ to X_{N} to the corresponding set of OR gates 755-1 to 755-N in response to the clock signal CLK (with the input to the SE input set accordingly), respectively. During a scan-in phase, the scan_enable is asserted at 1′b1 to maintain the TE inputs of the set of N cascaded CGC circuits 720-1 to 720-N at 1′b1 to enable the propagation of the clock signal CLK. At the end of the scan-in phase, the set of programmable test data X₁ to X_{N} at the Q outputs of the TE control registers 750-1 to 750-N are provided to the TE inputs of the set of N cascaded stage CGC circuits 720-1 to 720-N, respectively.

Considering first a stuck-at-one (SA1) fault testing at the CE input of the selected first stage CGC circuit 720-1, the dominant logic register 705 provides a 1′b0 to the CE inputs of the set of N cascaded CGC circuits 720-1 to 720-N in response to the clock signal CLK. As the first stage CGC circuit 720-1 is selected for testing, it is desired that the following subset of cascaded CGC circuits 720-2 to 720-N be transparent so that the clock signal CLK is able to propagate to the observation register 725 (e.g., transparent with respect to the clock signal path). Accordingly, in clock synchronous, the TE control registers 750-2 to 750-N provide test data X₂ to X_{N} at 1′b1s to the TE inputs of the cascaded CGC circuits 720-2 to 720-N, respectively. Again, as the first CGC circuit 720-1 is selected for testing, the first control register 750-1 provides a X₁=1′b0 to the TE input of the first stage CGC circuit 720-1 so that the logic state at its CE input controls the transferring of the clock signal CLK.

Thus, if there is a stuck-at-one (SA1) fault at the CE input of the first stage CGC circuit 720-1, a 1′b1 is at the CE input even though the dominant logic register 705 provided a 1′b0 to the CE input. Accordingly, the first stage CGC circuit 720-1 transfers the clock signal CLK to its Clk_out output for subsequent propagation to observation register 725 via the set of transparent CGC circuits 720-2 to 720-N. In response to the clock signal CLK at its clock input, the observation register 725 transfers the observation data (e.g., 1′b1) from the D or SIN input to the Q output, which was previously at the opposite logic state as that of the observation data (e.g., 1′b0). The transfer of the observation data causes the Q output to change logic states, which indicates a stuck-at-one (SA1) fault at the CE input of the first stage CGC circuit 720-1. If the Q output of the observation register 725 does not change state, this indicates no stuck-at-one (SA1) fault at the CE input of the first stage CGC circuit 720-1 as the 1′b0 provided to the CE input by the dominant logic register 705 prevented the transfer of the clock signal CLK by the first stage CGC circuit 720-1.

Considering next a stuck-at-one (SA1) fault testing at the CE input of a selected intermediate stage CGC circuit 720-i (where i is an integer, and 1<i<N). According to the test, the dominant logic register 705 provides a 1′b0 to the CE inputs of the set of N cascaded CGC circuits 720-1 to 720-N in response to the clock signal CLK. As the intermediate stage CGC circuit 720-i is selected for testing, it is desired that the preceding subset of cascaded CGC circuits 720-1 to 720-(i−1) and the following subset of cascaded CGC circuits 720-(i+1) to 720-N be transparent with respect to the clock signal path so that the clock signal CLK is able to propagate from the first stage CGC circuit 720-1 to the CGC circuit 720-i (under test), and from CGC circuit 720-i to CGC circuit 720-N, and finally to the observation register 725. Accordingly, in clock synchronous, the TE control registers 750-1 to 750-(i−1) and 750-(i+1) to 750-N provide X₁ to Xᵢ₊₁ and Xᵢ₋₁ to X_{N}=1′b1s to the TE inputs of the cascaded CGC circuits 720-1 to 720-(i−1) and 720-(i+1) to 720-N, respectively. Again, as the i^{th} CGC circuit 720-i is selected for testing, the i^{th} control register 750-i provides a Xᵢ=1′b0 to the TE input of the i^{th} stage CGC circuit 720-i so that the logic state at its CE input controls the transferring/forwarding of the clock signal CLK.

Thus, if there is a stuck-at-one (SA1) fault at the CE input of the i^{th} stage CGC circuit 720-1, a 1′b1 is at the CE input even though the dominant logic register 705 provided a 1′b0 to the CE input. Accordingly, the i^{th} stage CGC circuit 720-i transfers/forwards the clock signal CLK received from the preceding subset of transparent CGC circuits 720-1 to 720-(i−1) to its Clk_out output for subsequent propagation to observation register 725 via the subset of transparent CGC circuits 720-(i+1) to 720-N. In response to the clock signal CLK at its clock input, the observation register 725 transfers the observation data (e.g., 1′b1) from the D or SIN input to the Q output, which was previously at the opposite logic state as that of the observation data (e.g., 1′b0). The transfer of the observation data causes the Q output to change logic states, which indicates a stuck-at-one (SA1) fault at the CE input of the i^{th} stage CGC circuit 720-i. If the Q output of the observation register 725 does not change state, this indicates no stuck-at-one (SA1) fault at the CE input of the i^{th} stage CGC circuit 720-i as the 1′b0 provided to the CE input by the dominant logic register 705 prevented the transferring/forwarding of the clock signal CLK by the i^{th} stage CGC circuit 720-i.

Finally, considering a stuck-at-one (SA1) fault testing at the CE input of the selected last stage CGC circuit 720-N, the dominant logic register 705 provides a 1′b0 to the CE inputs of the set of N cascaded CGC circuits 720-1 to 720-N in response to the clock signal CLK. As the last stage CGC circuit 720-N is selected for testing, it is desired that the preceding subset of cascaded CGC circuits 720-1 to 720-(N−1) be transparent with respect to the clock signal path so that the clock signal CLK is able to propagate to the observation register 725. Accordingly, in clock synchronous, the TE control registers 750-1 to 750-(N−1) provide X₁ to X_{N-1}=1′b1s to the TE inputs of the cascaded CGC circuits 720-1 to 720-(N−1), respectively. Again, as the last CGC circuit 720-N is being tested, the last control register 750-1 provides a X_{N}=1′b0 to the TE input of the last stage CGC circuit 720-N so that the logic state at its CE input controls the transferring/forwarding of the clock signal CLK.

Thus, if there is a stuck-at-one (SA1) fault at the CE input of the last stage CGC circuit 720-N, a 1′b1 is at the CE input even though the dominant logic register 705 provided a 1′b0 to the CE input. Accordingly, the last stage CGC circuit 720-N transfers the clock signal CLK received from the preceding subset of transparent CGC circuits 720-1 to 720-(N−1) to its Clk_out output, and to the observation register 725. In response to the clock signal CLK at its clock input, the observation register 725 transfers the observation data (e.g., 1′b1) from the D or SIN input to the Q output, which was previously at the opposite logic state as that of the observation data (e.g., 1′b0). The transfer of the observation data causes the Q output to change logic states, which indicates a stuck-at-one (SA1) fault at the CE input of the last stage CGC circuit 720-N. If the Q output of the observation register 725 does not change state, this indicates no stuck-at-one (SA1) fault at the CE input of the last stage CGC circuit 720-N as the 1′b0 provided to the CE input by the dominant logic register 705 prevented the transfer/forwarding of the clock signal CLK by the last stage CGC circuit 720-N.

With further reference to ICs 300 and 600, for implementation detectability of the TE control registers 750-1 to 750-N in an IC, a set of multiplexers controlled by a set of JDR bits and configured in a similar manner as multiplexers 360 and 660 may be coupled in a feedback arrangement with the set of TE control registers 750-1 to 750-N, respectively. The detectability operation operates in a similarly manner:

When the JDR bits are 1′b1s, the operations of the TE control registers 750-1 to 750-N would be as previously described with reference to IC 600 (e.g., to provide 1′b1s to the TE inputs of the CGC circuits not-under-test). However, if the JDR bits are flipped to a 1′b0, after the clock edge causes the TE control registers 750-1 to 750-N to transfer the 1′b1s to the TE inputs of the CGC circuits 720-1 to 720-N, 1′b0s will end up at the D inputs of the TE control registers 750-1 to 750-N. When the vectors are scanned out for observation, the TE control registers 750-1 to 750-N will fail test because there is an expectation of 1′b1 s at the D inputs of the TE control registers 750-1 to 750-N when 1′b0s are observed at such D inputs. Thus, using this technique, detectability and locations of the TE control registers 750-1 to 750-N may be determined.

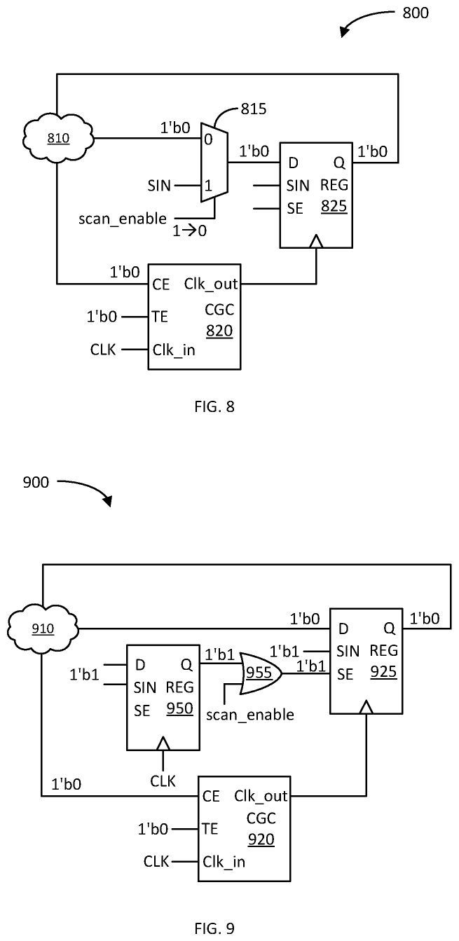

FIG. 8 illustrates a block diagram of an example integrated circuit (IC) 800 including design for testability (DFT) hardware for fault detection in a clock gate control (CGC) circuit in accordance with another aspect of the disclosure. The IC 800 includes an observation register 825, which also serves as the dominant logic for stuck-at-fault testing as described further herein. The IC 800 may further include some optional logic circuitry 810, a multiplexer 815, and a CGC circuit 820.

The observation register 825 includes a Q output configured to generate test data during a first cycle of a clock signal CLK, and generate a test result data during a next second cycle of the clock signal CLK, as explained in more detail further herein. The Q output of the observation register 825 is coupled to a CE input of the CGC circuit 820 and a “0” input of the multiplexer 815 via the logic circuitry 810. The CGC circuit 820 includes a TE input configured to receive a 1′b0 pursuant to a stuck-at-fault testing at its CE input as discussed further herein. Additionally, the CGC circuit 820 includes a Clk_in input configured to receive the clock signal CLK, and a Clk_out output configured to output the clock signal CLK based on data present at its CE and TE inputs. The Clk_out output of the CGC circuit 820 is coupled to a clock input of the observation register 825. The multiplexer 815 includes a “1” input configured to receive a scan in (SIN) signal, and a select input configured to receive a scan_enable signal. The multiplexer 815 includes an output coupled to the data (D) input of the observation register 825.

Based on the DFT hardware configuration of the IC 800, a test to determine a stuck-at-one (SA1) fault at the CE input of the CGC circuit 820 may not be achievable. For example, during a scan-in phase, the Q-output of the observation register 825 is set to a 1′b0, which is routed to the CE input of the CGC 820 and the “0” input of the multiplexer 815. The 1′b0 is routed to the CE input of the CGC 820 to test the input for a stuck-at-one (SA1) fault; which means that if there is no stuck-at-one (SA1) fault, the CE input is at 1′b0, whereas if there is a stuck-at-one (SA1) fault, the CE input is at 1′b1. When the scan-in phase ends with the scan_enable signal being deasserted (e.g., 1′b141′b0), the multiplexer 815 outputs the 1′b0 at its “0” input, and provides it to the D input of the observation register 825. As both the D input and Q output of the observation register 825 have the same logic state (1′b0), the testing of the CGC 820 may not be observable because the Q output of the observation register 825 will remain at the same logic state (1′b0) regardless of whether the CGC 820 outputs the clock signal CLK.

FIG. 9 illustrates a block diagram of another example integrated circuit (IC) 900 including design for testability (DFT) hardware for fault detection in a clock gate control (CGC) circuit in accordance with another aspect of the disclosure. The IC 900 includes a modification of the DFT hardware configuration of IC 800 to allow for testing for a stuck-at-one (SA1) fault at the CE input of a CGC circuit.

Accordingly, the IC 900 is a modified version of the IC 800, and includes a number of the same/similar elements as indicated by the same reference numbers with the exception that the most significant digit is a “9” in IC 900 compared to a “8” in IC 800. That is, the IC 900 includes a dominant logic, observation register 925, some optional logic circuitry 910, and a CGC circuit 920. Similarly, the observation register 925 includes a Q output configured to generate test data during a first cycle of a clock signal CLK, and generate a test result data during a next second cycle of the clock signal CLK, as previously discussed. The Q output of the observation register 925 is coupled to a CE input of the CGC circuit 920 and a D input of the observation register 925 via the logic circuitry 910 (e.g., a feedback arrangement). For a stuck-at-one (SA1) fault test at the CE input of the CGC circuit 920, the test data is a 1′b0 as shown.

The CGC circuit 920 includes a TE input configured to receive a 1′b0 pursuant to a stuck-at-fault testing at its CE input as discussed further herein. Additionally, the CGC circuit 920 includes a Clk_in input configured to receive the clock signal CLK (e.g., an input of the clock signal path), and a Clk_out output configured to output the clock signal CLK based on data present at its CE and TE inputs. The Clk_out output of the CGC circuit 920 is coupled to a clock input of the observation register 925 (e.g., an end or destination of the clock signal path).

As mentioned above, the IC 900 includes a DFT hardware configuration that allows for testing for a stuck-at-one (SA1) fault at the CE input of the stage CGC circuit 920. In this regard, the IC 900 includes a test enable (TE) control register 950 and an OR gate 955. The TE control register 950 may receive a programmable test data via the D or SIN input, and output the programmable test data to a first input of the OR gate 955 in response to the clock signal CLK (with the input to the SE input set accordingly). During scan-in phase, the scan_enable is asserted at 1′b1 to allow the TE control register 950 to provide a 1′b1 to the SE input of the observation register 925. The 1′b1 at the SE input instructs the observation register 925 to output the data at a SIN input, which, in this example, has been set to the opposite logic state (1′b1) as the Q output of the observation 925.

In this DFT hardware configuration, if the CE input of the CGC circuit 920 has a stuck-at-one (SA1) fault, the CE input is at a 1′b1 even though the dominant logic observation register 925 has provided a 1′b0 to the CE input. In response to the 1′b1 at the CE input, the CGC circuit 920 transfers the clock signal CLK at its Clk_in input to its Clk_out output, which is coupled to the clock input of the observation register 925. In response to the clock signal CLK, the observation register 925 transfers the 1′b1 data at its SIN input (as the data applied to the SE input is a 1′b1) to the Q output. As the Q output was previously at a 1′b0, the transfer of the 1′b1 causes a logic state change at the Q output, which indicates a stuck-at-one (SA1) fault at the CE input of the CGC circuit 920.

If the Q output of the observation register 925 does not change state (e.g., remains at 1′b0), this indicates that there is no stuck-at-one (SA1) fault at the CE input of the CGC circuit 920 as the 1′b0 at its CE input has instructed the CGC circuit 920 not to output the clock signal CLK.

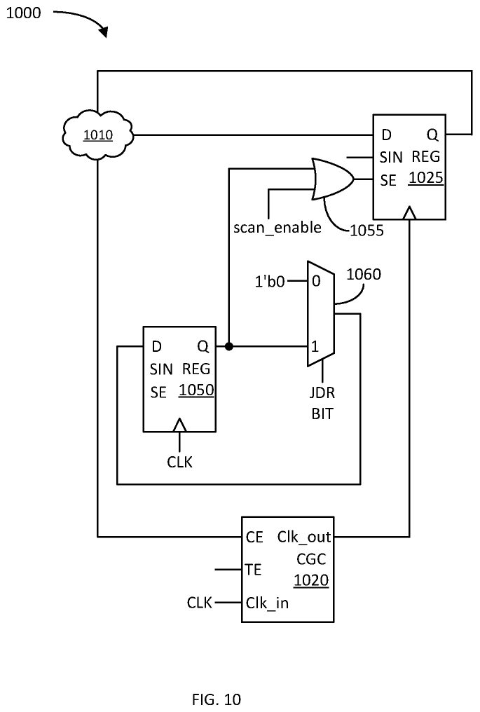

FIG. 10 illustrates a block diagram of another example integrated circuit (IC) 1000 including design for testability (DFT) hardware for fault detection in a clock gate control (CGC) circuit in accordance with another aspect of the disclosure. The IC 1000 is a variation of the IC 900 including many same/similar elements as indicated with the same reference numbers with the exception that the most significant digit is a “10” in IC 1000 compared to a “9” in IC 900.

In particular, the IC 1000 includes a dominant logic observation register 1025, some optional logic circuitry 1010, and a CGC circuit 1020. Additionally, to enable stuck-at-one (SA1) fault testing at the CE input of the CGC circuit 1020, as discussed in detail with reference to IC 900, the IC 1000 includes a TE control register 1050 and an OR gate 1055.

For implementation detectability, the IC 1000 includes a multiplexer 1060 including a “0” input configured to receive a 1′b0 bit, and a “1” input coupled to the Q output of the TE control register 1050. The multiplexer 1060 includes a select input configured to receive a JDR bit. When the JDR bit is a “1”, the operation of the TE control register 1050 is as described with reference to IC 900 (e.g., to provide a 1′b1 to the SE input of the observation register 1025). However, if the JDR bit is flipped to a “0”, after the clock edge causes the TE control register 1050 to transfer the 1′b1 to the SE input of the observation register 1025, a “0” ends up at the D input of the TE control register 1050. When the vectors are scanned out for observation, the TE control register 1050 will fail test because there is an expectation of a “1” at the D input of the TE control register 1050 when a “0” is observed at the D input. Thus, using this technique, the detectability and location of the TE control register 1050 may be determined.

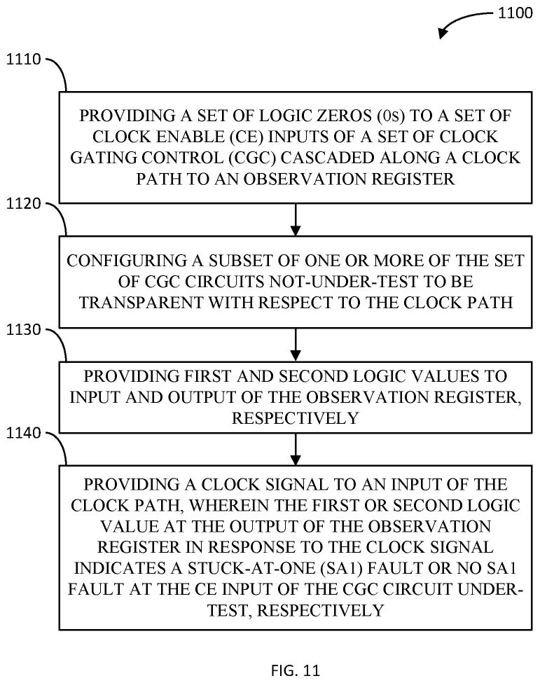

FIG. 11 illustrates a flow diagram of an example method 1100 of fault testing regarding a set of cascaded clock gate control (CGC) circuits in accordance with another aspect of the disclosure. The method 1100 includes providing a set of logic zeros (0s) to a set of clock enable (CE) inputs of a set of clock gating control (CGC) cascaded along a clock path to an observation register (block 1110). Additionally, the method 1100 includes configuring a subset of one or more of the set of CGC circuits not-under-test to be transparent with respect to the clock path (block 1120).

Further, the method 1100 includes providing first and second logic values to input and output of the observation register, respectively (block 1130). And, the method 1100 includes providing a clock signal to an input of the clock path, wherein the first or second logic value at the output of the observation register in response to the clock signal indicates a stuck-at-one (SA1) fault or no SA1 fault at the CE input of the CGC circuit under-test, respectively (block 1140).

Although not explicitly depicted in FIG. 11, according to the method 1100, configuring the subset of one or more CGC circuits not-under-test to be transparent with respect to the clock path may comprise providing one or more logic ones (1s) to one or more test enable (TE) inputs of the one or more CGC circuits not-under-test, respectively. Additionally, the method 1100 may include providing a logic zero (0) to a test enable (TE) input of the CGC circuit under-test. And, according to the method 1100, the first and second logic values may be opposite logic values.

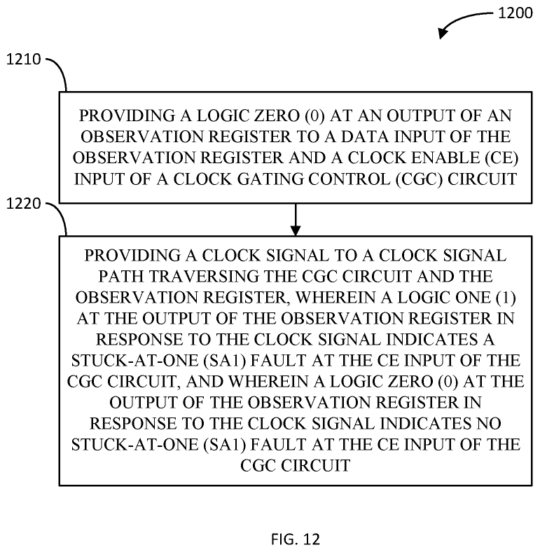

FIG. 12 illustrates a flow diagram of an example method 1200 of fault testing a clock gate control (CGC) circuit in accordance with another aspect of the disclosure. The method 1200 includes providing a logic zero (0) at an output of an observation register to a data input of the observation register and a clock enable (CE) input of a clock gating control (CGC) circuit (block 1210). The method 1200 additionally includes providing a clock signal to a clock signal path including the CGC circuit and the observation register, wherein a logic one (1) at the output of the observation register in response to the clock signal indicates a stuck-at-one (SA1) fault at the CE input of the CGC circuit, and wherein a logic zero (0) at the output of the observation register in response to the clock signal indicates no stuck-at-one (SA1) fault at the CE input of the CGC circuit (block 1220).

Although not explicitly depicted in FIG. 12, the method 1200 may further include providing a logic one (1) to a scan-in (SIN) input of the observation register, wherein the logic one (1) at the output of the observation register in response to the clock signal comes from the logic one (1) at the SIN input of the observation register. Further, the method 1200 may include providing a logic one (1) to a scan-enable (SE) input of the observation register to allow the logic one (1) at the SIN input to propagate to the output of the observation register in response to the clock signal if the SA1 fault is present at the CE input of the CGC circuit. Additionally, the method 1200 may include providing a logic zero (0) to a test enable (TE) input of the CGC circuit to allow for the SA1 fault testing of the CE input of the CGC circuit.

The following provides an overview of aspects of the present disclosure:

Aspect 1: An integrated circuit (IC), including: a set of cascaded clock gating control (CGC) circuits, wherein a first one of the set of cascaded CGC circuits includes a clock input configured to receive a clock signal; an observation register including a clock input coupled to a clock output of a last one of the set of cascaded CGC circuits; an input register configured to provide logic zeros (0s) to clock enable (CE) inputs of the set of cascaded CGC circuits pursuant to a stuck-at-one (SA1) fault testing on the CE input of a selected one of the set of cascaded CGC circuits; and a set of one or more test enable (TE) control registers configured to provide one or more logic ones (1s) to one or more TE inputs of one or more of the set of cascaded CGC circuits not undergoing the stuck-at-one (SA1) fault testing, respectively.

Aspect 2: The IC of aspect 1, wherein if there is a stuck-at-one (SA1) fault at the CE input of the selected CGC circuit, the set of cascaded CGC circuits is configured to propagate the clock signal from the clock input of the first one of the set of cascaded CGC circuits to the clock input of the observation register.

Aspect 3: The IC of aspect 2, wherein the observation register is configured to change a logic state at an output in response to the clock signal at the clock input of the observation register, wherein the change in the logic state indicates the stuck-at-one (SA1) fault at the CE input of the selected CGC circuit.

Aspect 4: The IC of any one of aspects 1-3, wherein if there is no stuck-at-one (SA1) fault at the CE input of the selected CGC circuit, the set of cascaded CGC circuits is not configured to propagate the clock signal from the clock input of the first one of the set of cascaded CGC circuit to the clock input of the observation register.

Aspect 5: The IC of aspect 4, wherein the observation register is configured not to change a logic state at an output when the clock signal does not propagate to the clock input of the observation register, wherein the no change in the logic state indicates that there is no stuck-at-one (SA1) fault at the CE input of the selected CGC circuit.

Aspect 6: The IC of any one of aspects 1-5, further comprising a set of one or more OR gates including: a set of one or more first inputs coupled to the set of one or more TE control registers, respectively; a set of one or more second inputs configured to receive a scan_enable signal; and a set of one or more outputs coupled to the one or more TE inputs of the set of cascaded CGC circuits, respectively.

Aspect 7: The IC of any one of aspects 1-6, further comprising a set of one or more multiplexers including a first set of one or more inputs configured to receive a logic zero (0), a second set of one or more inputs coupled to one or more outputs of the set of one or more TE control registers, a third set of one or more inputs configured to receive a set of one or more Joint Test Action Group (JTAG) data register (JDR) bits, and a set of one or more outputs coupled to one or more inputs of the set of one or more TE control registers, respectively.

Aspect 8: The IC of any one of aspects 1-7, further comprising another test enable (TE) control register configured to provide a logic zero (0) to the CE input of the selected CGC circuit.

Aspect 9: The IC of aspect 8, further comprising a set of OR gates including: a set of first inputs coupled to the set of one or more TE control registers and the another TE control register, respectively; a set of second inputs configured to receive a scan_enable signal; and a set of outputs coupled to the TE inputs of the set of cascaded CGC circuits, respectively.

Aspect 10: The IC of aspect 9, further comprising a set multiplexers including a first set inputs configured to receive a logic zero (0), a second set of inputs coupled to outputs of the set of one or more TE control registers and the another TE control register, a third set of inputs configured to receive a set of Joint Test Action Group (JTAG) data register (JDR) bits, and a set of outputs coupled to inputs of the set of one or more TE control registers and the another TE control register, respectively.

Aspect 11: A method, comprising: providing a set of logic zeros (0s) to a set of clock enable (CE) inputs of a set of clock gating control (CGC) cascaded along a clock path to an observation register; configuring a subset of one or more of the set of CGC circuits not-under-test to be transparent with respect to the clock path; providing first and second logic values to input and output of the observation register, respectively; and providing a clock signal to an input of the clock path, wherein the first or second logic value at the output of the observation register in response to the clock signal indicates a stuck-at-one (SA1) fault or no SA1 fault at the CE input of the CGC circuit under-test, respectively.

Aspect 12: The method of aspect 11, wherein configuring the subset of one or more CGC circuits not-under-test to be transparent with respect to the clock path comprises providing one or more logic ones (1s) to one or more test enable (TE) inputs of the one or more CGC circuits not-under-test, respectively.

Aspect 13: The method of aspect 11 or 12, further comprising providing a logic zero (0) to a test enable (TE) input of the CGC circuit under-test.

Aspect 14: The method of any one of aspects 11-13, wherein the first and second logic values are opposite logic values.

Aspect 15: An integrated circuit (IC), including: a clock gating control (CGC) circuit including a clock enable (CE) input, a clock input configured to receive a clock signal, and a clock output; an observation register including a data input, a clock input coupled to the clock output of the CGC circuit, a data output coupled to the CE input of the CGC circuit and the data input of the observation register, a scan-in (SIN) input configured to receive a logic one (1), and a scan enable (SE) input, wherein the observation register is configured to provide logic zeros (0s) to the CE input of the CGC circuit and the data input of the observation register pursuant to a stuck-at-one (SA1) fault testing on the CE input of the CGC circuit; and a test enable (TE) control register configured to provide a logic one (1) to the SE input of the observation register pursuant to the stuck-at-one (SA1) fault testing at the CE input of the CGC circuit.

Aspect 16: The IC of aspect 15, wherein if there is a stuck-at-one (SA1) fault at the CE input of the CGC circuit, the CGC circuit is configured to propagate the clock signal from the clock input to the clock output for providing the clock signal to the clock input of the observation register.

Aspect 17: The IC of aspect 16, wherein the observation register is configured to transfer the logic one (1) at the SIN input to the data output in response to the clock signal at the clock input of the observation register, wherein the logic one (1) at the data output indicates the stuck-at-one (SA1) fault at the CE input of the CGC circuit.

Aspect 18: The IC of any one of aspects 15-17, wherein if there is no stuck-at-one (SA1) fault at the CE input of the CGC circuit, the CGC circuit is not configured to propagate the clock signal from the clock input to the clock output such that the clock signal is not provided to the clock input of the observation register.

Aspect 19: The IC of aspect 18, wherein the observation register is not configured to transfer the logic one (1) at the SIN input to the data output in the absence of the clock signal at the clock input of the observation register, wherein a logic zero (0) at the data output indicates no stuck-at-one (SA1) fault at the CE input of the CGC circuit.

Aspect 20: The IC of any one of aspects 15-19, further comprising an OR gate including a first input coupled to an output of the TE control register, a second input configured to receive a scan_enable signal, and an output coupled to the SE input of the observation register.

Aspect 21: The IC of any one of aspects 15-20, further comprising a multiplexer including a first input configured to receive a logic zero (0), a second input coupled to an output of the TE control register, a third input configured to receive a Joint Test Action Group (JTAG) data register (JDR) bit, and an output coupled to an input of the TE control register.

Aspect 22: A method, comprising: providing a logic zero (0) at an output of an observation register to a data input of the observation register and a clock enable (CE) input of a clock gating control (CGC) circuit; and providing a clock signal to a clock signal path including the CGC circuit and the observation register, wherein a logic one (1) at the output of the observation register in response to the clock signal indicates a stuck-at-one (SA1) fault at the CE input of the CGC circuit, and wherein a logic zero (0) at the output of the observation register in response to the clock signal indicates no stuck-at-one (SA1) fault at the CE input of the CGC circuit.

Aspect 23: The method of aspect 22, further comprising providing a logic one (1) to a scan-in (SIN) input of the observation register, wherein the logic one (1) at the output of the observation register in response to the clock signal comes from the logic one (1) at the SIN input of the observation register.

Aspect 24: The method of aspect 23, further comprising providing a logic one (1) to a scan-enable (SE) input of the observation register to allow the logic one (1) at the SIN input to propagate to the output of the observation register in response to the clock signal if the SA1 fault is present at the CE input of the CGC circuit.

Aspect 25: The method of any one of aspects 22-24, further comprising providing a logic zero (0) to a test enable (TE) input of the CGC circuit to allow for the SA1 fault testing of the CE input of the CGC circuit.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed:

1. An integrated circuit (IC), comprising:
a set of cascaded clock gating control (CGC) circuits, wherein a first one of the set of cascaded CGC circuits includes a clock input configured to receive a clock signal;
an observation register including a clock input coupled to a clock output of a last one of the set of cascaded CGC circuits;
an input register configured to provide logic zeros (0s) to clock enable (CE) inputs of the set of cascaded CGC circuits pursuant to a stuck-at-one (SA1) fault testing on the CE input of a selected one of the set of cascaded CGC circuits; and
a set of one or more test enable (TE) control registers configured to provide one or more logic ones (1s) to one or more TE inputs of one or more of the set of cascaded CGC circuits not undergoing the stuck-at-one (SA1) fault testing, respectively.

2. The IC of claim 1, wherein if there is a stuck-at-one (SA1) fault at the CE input of the selected CGC circuit, the set of cascaded CGC circuits is configured to propagate the clock signal from the clock input of the first one of the set of cascaded CGC circuits to the clock input of the observation register.

3. The IC of claim 2, wherein the observation register is configured to change a logic state at an output in response to the clock signal at the clock input of the observation register, wherein the change in the logic state indicates the stuck-at-one (SA1) fault at the CE input of the selected CGC circuit.

4. The IC of claim 1, wherein if there is no stuck-at-one (SA1) fault at the CE input of the selected CGC circuit, the set of cascaded CGC circuits is not configured to propagate the clock signal from the clock input of the first one of the set of cascaded CGC circuit to the clock input of the observation register.

5. The IC of claim 4, wherein the observation register is configured not to change a logic state at an output when the clock signal does not propagate to the clock input of the observation register, wherein the no change in the logic state indicates that there is no stuck-at-one (SA1) fault at the CE input of the selected CGC circuit.

6. The IC of claim 1, further comprising a set of one or more OR gates including:
a set of one or more first inputs coupled to the set of one or more TE control registers, respectively;
a set of one or more second inputs configured to receive a scan_enable signal; and
a set of one or more outputs coupled to the one or more TE inputs of the set of cascaded CGC circuits, respectively.

7. The IC of claim 1, further comprising a set of one or more multiplexers including a first set of one or more inputs configured to receive a logic zero (0), a second set of one or more inputs coupled to one or more outputs of the set of one or more TE control registers, a third set of one or more inputs configured to receive a set of one or more Joint Test Action Group (JTAG) data register (JDR) bits, and a set of one or more outputs coupled to one or more inputs of the set of one or more TE control registers, respectively.

8. The IC of claim 1, further comprising another test enable (TE) control register configured to provide a logic zero (0) to the CE input of the selected CGC circuit.

9. The IC of claim 8, further comprising a set of OR gates including:
a set of first inputs coupled to the set of one or more TE control registers and the another TE control register, respectively;
a set of second inputs configured to receive a scan_enable signal; and
a set of outputs coupled to the TE inputs of the set of cascaded CGC circuits, respectively.

10. The IC of claim 9, further comprising a set multiplexers including a first set inputs configured to receive a logic zero (0), a second set of inputs coupled to outputs of the set of one or more TE control registers and the another TE control register, a third set of inputs configured to receive a set of Joint Test Action Group (JTAG) data register (JDR) bits, and a set of outputs coupled to inputs of the set of one or more TE control registers and the another TE control register, respectively.

11. A method, comprising:
providing a set of logic zeros (0s) to a set of clock enable (CE) inputs of a set of clock gating control (CGC) cascaded along a clock path to an observation register;
configuring a subset of one or more of the set of CGC circuits not-under-test to be transparent with respect to the clock path;
providing first and second logic values to input and output of the observation register, respectively; and
providing a clock signal to an input of the clock path, wherein the first or second logic value at the output of the observation register in response to the clock signal indicates a stuck-at-one (SA1) fault or no SA1 fault at the CE input of the CGC circuit under-test, respectively.

12. The method of claim 11, wherein configuring the subset of one or more CGC circuits not-under-test to be transparent with respect to the clock path comprises providing one or more logic ones (1s) to one or more test enable (TE) inputs of the one or more CGC circuits not-under-test, respectively.

13. The method of claim 11, further comprising providing a logic zero (0) to a test enable (TE) input of the CGC circuit under-test.

14. The method of claim 11, wherein the first and second logic values are opposite logic values.

15. An integrated circuit (IC), comprising:
a clock gating control (CGC) circuit including a clock enable (CE) input, a clock input configured to receive a clock signal, and a clock output;
an observation register including a data input, a clock input coupled to the clock output of the CGC circuit, a data output coupled to the CE input of the CGC circuit and the data input of the observation register, a scan-in (SIN) input configured to receive a logic one (1), and a scan enable (SE) input, wherein the observation register is configured to provide logic zeros (0s) to the CE input of the CGC circuit and the data input of the observation register pursuant to a stuck-at-one (SA1) fault testing on the CE input of the CGC circuit; and
a test enable (TE) control register configured to provide a logic one (1) to the SE input of the observation register pursuant to the stuck-at-one (SA1) fault testing at the CE input of the CGC circuit.

16. The IC of claim 15, wherein if there is a stuck-at-one (SA1) fault at the CE input of the CGC circuit, the CGC circuit is configured to propagate the clock signal from the clock input to the clock output for providing the clock signal to the clock input of the observation register.

17. The IC of claim 16, wherein the observation register is configured to transfer the logic one (1) at the SIN input to the data output in response to the clock signal at the clock input of the observation register, wherein the logic one (1) at the data output indicates the stuck-at-one (SA1) fault at the CE input of the CGC circuit.

18. The IC of claim 15, wherein if there is no stuck-at-one (SA1) fault at the CE input of the CGC circuit, the CGC circuit is not configured to propagate the clock signal from the clock input to the clock output such that the clock signal is not provided to the clock input of the observation register.

19. The IC of claim 18, wherein the observation register is not configured to transfer the logic one (1) at the SIN input to the data output in the absence of the clock signal at the clock input of the observation register, wherein a logic zero (0) at the data output indicates no stuck-at-one (SA1) fault at the CE input of the CGC circuit.

20. The IC of claim 15, further comprising an OR gate including a first input coupled to an output of the TE control register, a second input configured to receive a scan_enable signal, and an output coupled to the SE input of the observation register.

21. The IC of claim 15, further comprising a multiplexer including a first input configured to receive a logic zero (0), a second input coupled to an output of the TE control register, a third input configured to receive a Joint Test Action Group (JTAG) data register (JDR) bit, and an output coupled to an input of the TE control register.

22. A method, comprising:
providing a logic zero (0) at an output of an observation register to a data input of the observation register and a clock enable (CE) input of a clock gating control (CGC) circuit; and
providing a clock signal to a clock signal path including the CGC circuit and the observation register, wherein a logic one (1) at the output of the observation register in response to the clock signal indicates a stuck-at-one (SA1) fault at the CE input of the CGC circuit, and wherein a logic zero (0) at the output of the observation register in response to the clock signal indicates no stuck-at-one (SA1) fault at the CE input of the CGC circuit.

23. The method of claim 22, further comprising providing a logic one (1) to a scan-in (SIN) input of the observation register, wherein the logic one (1) at the output of the observation register in response to the clock signal comes from the logic one (1) at the SIN input of the observation register.

24. The method of claim 23, further comprising providing a logic one (1) to a scan-enable (SE) input of the observation register to allow the logic one (1) at the SIN input to propagate to the output of the observation register in response to the clock signal if the SA1 fault is present at the CE input of the CGC circuit.

25. The method of claim 22, further comprising providing a logic zero (0) to a test enable (TE) input of the CGC circuit to allow for the SA1 fault testing of the CE input of the CGC circuit.
